(19) United States
(12) Patent Application Publication
(10) Pub. No.: US 2008/0117691 A1
(43) Pub. Date: May 22, 2008

(54) ERASING CIRCUIT OF NONVOLATILE SEMICONDUCTOR MEMORY DEVICE

(75) Inventor: Youichi KAWASAKI, Fukuyama-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/940,189

(22) Filed: Nov. 14, 2007

(30) Foreign Application Priority Data
Nov. 17, 2006 (JP) 2006-311956
Feb. 9, 2007 (JP) 2007-030701

(51) Int. Cl. G11C 16/16

(52) U.S. Cl. 365/185.33

(57) ABSTRACT

A nonvolatile semiconductor memory device allowing a chip area to be small without complicating the control of erasing process and providing a boundary region for insulating each memory cell block electrically, comprises a memory cell array formed in a well region of a second conductivity type on a semiconductor substrate of a first conductivity type, having memory cells arranged in row and column directions like a matrix such that control gates of the memory cells in a row are connected to a common word line, and divided into memory cell blocks including word lines, and performs an erasing process for each memory cell block by applying erasing positive voltage to the well region, erasing negative voltage to all the word lines in an erasing object block, and the erasing positive voltage to control gates of all the memory cells in the memory cell blocks except for the erasing object block.

### CROSS REFERENCE TO RELATED APPLICATION

This Nonprovisional application claims priority under 35 U.S.C. § 119(a) on Patent Application No. 2006-311956 filed in Japan on 17 Nov., 2006 and Patent Application No. 2007-030701 filed in Japan on 9 Feb., 2007 the entire contents of which are hereby incorporated by reference.

### BACKGROUND OF THE INVENTION

1. Field of the Invention

The present invention relates to a nonvolatile semiconductor memory device executing an erasing process with respect to each memory cell block.

2. Description of the Related Art

In general, a nonvolatile semiconductor memory device such as a flash EEPROM (Electronically Erasable and Programmable Read Only Memory) includes a memory cell array containing a plurality of memory cells each having an electrically writable MOS transistor structure in which a charge accumulation layer capable of accumulating electric charges and a control gate are laminated in a well region of a second conductivity type (P-type, for example) formed on a semiconductor substrate of a first conductivity type (N-type, for example). Generally in such a flash EEPROM, an erasing process can be selectively executed with respect to each memory cell block in order to reduce an area of the memory cell array and increase a speed of the erasing process.

The erasing process of the nonvolatile semiconductor memory device such as the flash EEPROM includes an erasing process in which a high positive voltage (8 V, for example) is applied to a well region having memory cells and a reference voltage (ground voltage 0 V, for example) or a negative voltage lower than the reference voltage (−8 V, for example) is applied to a control gate to draw an electric charge from a floating gate to the well region, and an erasing process in which a high positive voltage is applied to a source of a memory cell and the reference voltage is applied to a control gate to draw an electric charge from the floating gate to the source.

According to the nonvolatile semiconductor memory device in which the erasing process is performed by applying a high electric field between the control gate and the well region, in order to perform the erasing process selectively with respect to each memory cell block, a boundary region for electrically insulating the well region in which each memory cell block is formed is provided between the memory cell blocks.

FIG. 5 shows the constitution of a memory cell array of a general NOR type flash EEPROM. This memory cell array is divided into two memory cell blocks MB1 and MB2, and a boundary region BO12 is provided between the memory cell block MB1 and the memory cell block MB2. A P-type well region PW₁ in which the memory cell block MB1 is formed and a P-type well region PW₂ in which the memory cell block MB2 is formed are electrically insulated by the boundary region BO12, so that the memory cell block MB1 and the memory cell block MB2 can be selectively erased. More specifically, in an erasing process, when it is assumed that the memory cell block MB1 is an erasing object block and the memory cell block MB2 is a non-erasing object block, the data in the memory cell block MB1 can be erased by applying a high positive voltage to the P-type well region PW₁ of the memory cell block MB1 that is the erasing object block, and applying a negative voltage to word lines WL₁₁ to WL₁ₙ in the memory cell block MB1. In addition, a voltage is not applied to the P-type well region PW₂ of the memory cell block MB2 that is the non-erasing object block and word lines WL₂₁ to WL₂ₙ in the memory cell block MB2. Thus, the P-type well region PW₂ of the memory cell block MB2 and the word lines WL₂₁ to WL₂ₙ contained in the memory cell block MB2 are at the same voltage (0 V, for example), so that its programmed data is not erased but protected.

Such a nonvolatile semiconductor memory device includes one in which a plurality of memory cell blocks provided by dividing a memory cell array are formed in a well region of a second conductivity type which is formed on a semiconductor substrate of a first conductivity type, and the memory cell blocks are separated by a diffusion layer (wiring) of the first conductivity type, and a well potential setting electrode is provided for each memory cell block, to execute the erasing process with respect to each memory cell block (refer to Japanese Laid-Open Patent Publication No. 3-290960).

However, in the nonvolatile semiconductor memory device according to the above conventional technique, since the voltage value of the well region in which the memory cell block MB1 is formed and the voltage value of the well region in which the memory cell block MB2 is formed are different, at the time of erasing process, that is, the voltage value of the well region of the erasing object block and the voltage value of the well region of the non-erasing object block are different, it is necessary to insulate the memory cell block from each other. That is, since it is necessary to provide a boundary region for electrically insulating each memory cell block, between memory cell blocks, a chip area is increased and a manufacturing cost cannot be sufficiently reduced.

Meanwhile, there is a nonvolatile semiconductor memory device that can perform the erasing process with respect to each word line by applying the ground voltage to a control gate, an erasing high voltage to a source of an erasing object cell, and applying an erasing high voltage to control gates and sources of memory cells except for the erasing object cell (refer to Japanese Laid-Open Patent Publication No. 4-355299, for example). According to such a nonvolatile semiconductor memory device, since erasing process is performed with respect to each word line by controlling the voltage applied to the control gate and the source such that a high electric field is applied between the control gate and the source, it is not necessary to provide a boundary region for electrically insulating each memory cell block, between memory cell blocks, so that the chip area can be prevented from being increased.

However, according to the nonvolatile semiconductor memory device disclosed in the Japanese Laid-Open Patent Publication No. 4-355299, since the erasing process is implemented by controlling the voltage applied to the control gate and the source, there is a problem that the control regarding the erasing process becomes complicated.

### SUMMARY OF THE INVENTION

The present invention was made to solve the above problems and it is an object of the present invention to provide a nonvolatile semiconductor memory device in which at the time of erasing process performed with respect to each memory cell block, a chip area can be small without complicating the control of the erasing process and without providing a boundary region for insulating each memory cell block electrically.

A nonvolatile semiconductor memory device according to the present invention to attain the above object includes a memory cell array including a plurality of memory cells having an electrically writable MOS transistor structure provided by laminating a charge accumulation layer capable of accumulating electric charges and a control gate, the memory cell array being formed in a well region of a second conductivity type different from a first conductivity type, the well region being formed on a semiconductor substrate of the first conductivity type, wherein the memory cell array includes the memory cells arranged in row and column directions like a matrix such that the control gates of the memory cells in the same row are connected to a common word line, drains of the memory cells in the same column are connected to a common bit line, and sources of the memory cells at least in the same column or the same row are connected to a common ground line, and the memory cell array is divided into a plurality of memory cell blocks each including a plurality of word lines, and an erasing process is performed with respect to each memory cell block by applying an erasing positive voltage to the well region, an erasing negative voltage to all the word lines contained in an erasing object block in the memory cell blocks, and the erasing positive voltage to the control gates of all the memory cells included in the memory cell blocks except for the erasing object block.

The nonvolatile semiconductor memory device having the above characteristics includes a plurality of memory cell block groups each having the plurality of memory cell blocks formed in the common well region, the well region of the memory cell block group being electrically separated from the well region of the adjacent memory cell block group, wherein the erasing process is performed to the erasing object block by applying the erasing positive voltage to the well region, the erasing negative voltage to all the word lines contained in the erasing object block, and the erasing positive voltage to all the word lines contained in the memory cell blocks except for the erasing object block in a selected memory cell block group including the erasing object block, and by applying a predetermined reference voltage to the well region, and applying the reference voltage to all the word lines contained in all the memory cell blocks or bringing them to a floating state in an unselected memory cell block group not including the erasing object block.

The nonvolatile semiconductor memory device having one of the above characteristics further includes a row decoder capable of switching the voltage to be applied to the word lines of each of the memory cell blocks at the erasing process with respect to each memory cell block, and a voltage supply source provided for each memory cell block of the memory cell block group and switching to supply the reference voltage or the erasing positive voltage to the row decoder of one of the memory cell blocks in the memory cell block group, wherein each of the voltage supply sources outputs the reference voltage when the erasing object block is included in the memory cell blocks receiving the voltage in common between the memory cell block groups, and outputs the erasing positive voltage when the erasing object block is not included therein.

According to the present invention having the above characteristics, since the memory cell blocks are formed in the same well region and at the time of erasing process, the erasing positive voltage is applied to the well region, the erasing negative voltage is applied to all the word lines in the erasing object block, and the erasing positive voltage is applied to the control gates of all the memory cells included in the memory cell blocks except for the erasing object block (non-erasing object block), the erasing process can be performed only by controlling the voltage to the well region and the control gate (word line) of each memory cell. Thus, according to the present invention, since it is not necessary to provide the boundary region for insulating the memory cell block electrically from each other, between the memory cell blocks, the chip area can be small. Furthermore, since the same erasing positive voltage as to the well region is applied to the word line of the non-erasing object block, the holding characteristics of the data of each memory cell is not adversely affected.

On the other hand, when the erasing process is performed with respect to each word line, for example, since the erasing negative voltage is applied to the word line connected to an erasing object cell in the memory cells and the erasing positive voltage is applied to the word line connected to an adjacent non-erasing object cell, the voltage difference is very large between the adjacent word lines. Meanwhile, according to the present invention, when the erasing process is performed with respect to each memory cell block, there is no voltage difference between the word lines. However, when the erasing process is performed with respect to each word line, it is necessary that the word lines in the memory cell block are separated from each other and the row decoder is provided so as to control the voltage applied to each of the separated word lines. Meanwhile, according to the present invention, when the erasing process is performed with respect to each memory cell block, since the voltage applied to the word lines in the same memory cell block is the same, the row decoder can be simple in constitution.

### BRIEF DESCRIPTION OF THE DRAWINGS

FIG. 1 is a schematic block diagram showing one example of a constitution regarding an erasing process in a first embodiment of a nonvolatile semiconductor memory device according to the present invention;

FIG. 2 is a schematic waveform chart showing a voltage waveform applied to a well region and a word line, in the erasing process of the device of the present invention;

FIG. 3 is a schematic layout chart showing a layout example of a memory cell array in the nonvolatile semiconductor memory device according to the present invention;

FIG. 4 is a schematic layout chart showing a layout example of a memory cell array according to another embodiment in the nonvolatile semiconductor memory device according to the present invention;

FIG. 5 is a schematic layout chart showing a layout example of a memory cell array in a conventional nonvolatile semiconductor memory device;

FIG. 6 is a schematic block diagram showing one example of a constitution regarding the erasing process in a second embodiment of the nonvolatile semiconductor memory device according to the present invention; and

FIG. 7 is a schematic block diagrams showing one example of a constitution regarding the erasing process in another embodiment of the nonvolatile semiconductor memory device according to the present invention.

### DETAILED DESCRIPTION OF THE INVENTION

Description will be made of embodiments of a nonvolatile semiconductor memory device according to the present invention (referred to as “device of the present invention” occasionally hereinafter) with reference to the drawings.

### First Embodiment

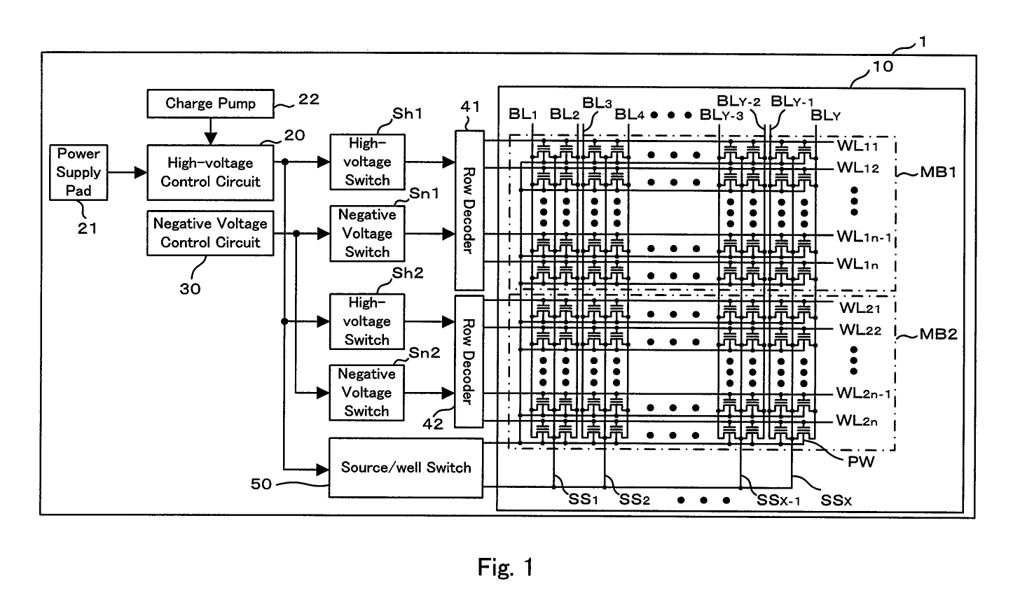

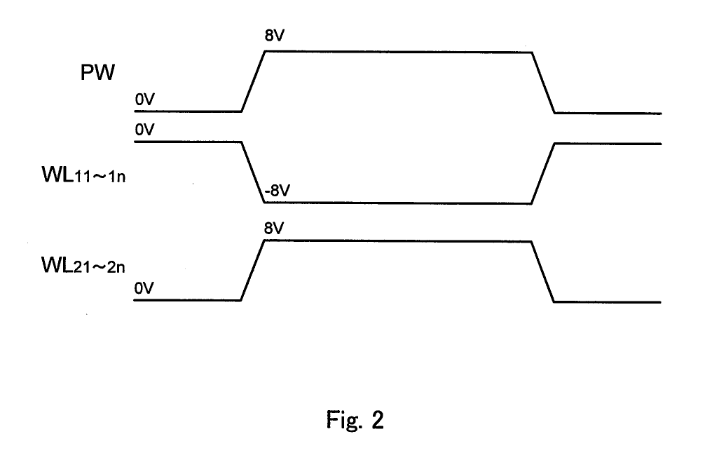

The first embodiment of the device of the present invention will be described with reference to FIGS. 1 to 3. FIG. 1 is a schematic block diagram showing one example of a constitution regarding an erasing process of the device of the present invention, and FIG. 2 is a schematic waveform diagram showing a voltage waveform applied to a well region and each word line. In addition, according to the present embodiment, description will be made of a case where a memory cell array is divided into two memory cell blocks.

The device of the present invention is constituted to perform an erasing process with respect to each memory cell block in such a manner that an erasing positive voltage is applied to the well region, an erasing negative voltage is applied to all the word lines contained in an erasing object block in the memory cell block, and the erasing positive voltage is applied to control gates of all memory cells included in the memory cell blocks except for the erasing object block.

More specifically, as shown in FIG. 1, a device 1 of the present invention includes a memory cell array 10 divided into two memory cell blocks MB1 and MB2, a high-voltage control circuit 20 receiving a voltage outputted from a power supply pad 21 that receives an external power supply Vpp or a charge pump 22, and generating an erasing positive voltage (8 V, for example) to be used in the erasing process, and supplying it to high-voltage switches Sh1 and Sh2 and a source/well switch 50, a negative voltage control circuit 30 generating an erasing negative voltage (−8 V, for example) that is lower than a reference voltage (ground voltage, 0 V) to be used in the erasing process and supplying it to negative voltage switches Sn1 and Sn2, a row decoder 41 receiving voltages from the high-voltage switch Sh1 and the negative voltage switch Sn1 and applying a voltage to the word line of the memory cell block MB1 according to a selected state, a row decoder 42 receiving voltages from the high-voltage switch Sh2 and the negative voltage switch Sn2 and applying a voltage to the word line of the memory cell block MB2 according to a selected state, and the source/well switch 50 receiving the output from the high-voltage control circuit 20 and applying a voltage to source straps SS₁ to SSₓ (corresponding to the ground line) connected to the sources of the memory cells or a P-type well region PW. In addition, according to the present embodiment, description will be made of a case where the memory cell block MB1 is the erasing object block and the memory cell block MB2 is a non-erasing object block to hold programmed data.

As shown in FIG. 1, the memory cell array 10 is formed in the well region PW of a second conductivity type (P-type, for example) that is different from a first conductivity type and formed on a semiconductor substrate of the first conductivity type (N-type, for example). The memory cell array 10 includes a plurality of memory cells arranged like a matrix in row and column directions and each having an electrically writable MOS transistor in which a charge accumulation layer that can accumulate electric charges and a control gate are laminated, in which the control gates of the memory cells in the same row are connected to each of common word lines WL₁₁ to WL₁ₙ and WL₂₁ to WL₂ₙ, the drains of the memory cells in the same column are connected to each of common bit lines BL₁ to BL_{Y}, and the sources of the memory cells in at least the same column or same row are connected to each of the common source straps SS₁ to SS_{X} (corresponding to the ground line).

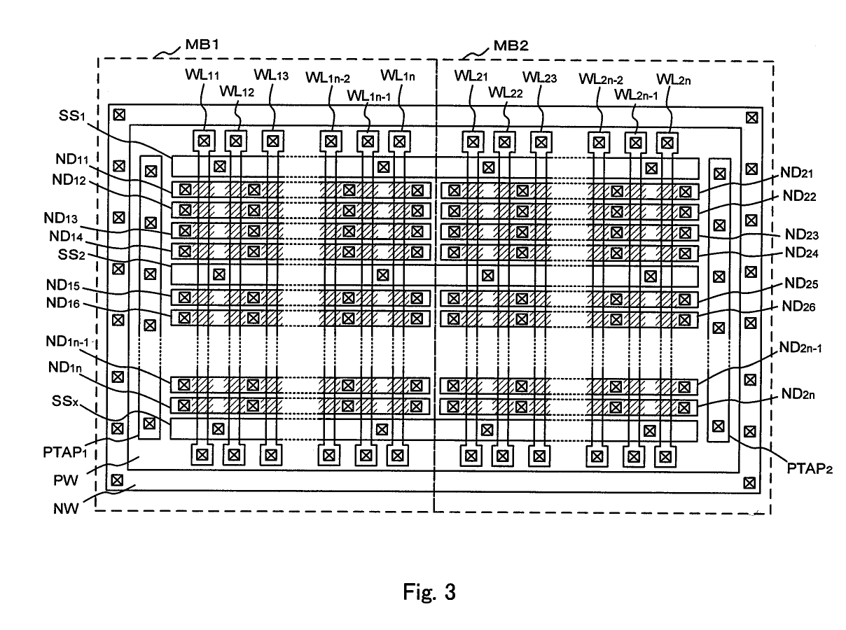

FIG. 3 is a schematic layout chart showing a layout example of the memory cell array 10. The P-type well region PW is formed on an N-type semiconductor substrate NW, and the memory cell array 10 formed in the same P-type well region is divided into the two memory cell blocks MB1 and MB2. The memory cell block MB1 includes word lines WL₁₁ to WL₁ₙ and N+ diffusion regions ND₁₁ to ND₁ₙ, and the word lines WL₁₁ to WL₁ₙ and N+ diffusion regions ND₁₁ to ND₁ₙ are intersect at right angles with each other. Memory cells of the memory cell block MB1 are formed at overlapping parts (shown by slanted lines) of the word lines WL₁₁ to WL₁ₙ and N+ diffusion regions ND₁₁ to ND₁ₙ and a part that is in contact with the drain is a bit line and a part that is not in contact with the drain is a source. Similarly, the memory cell block MB2 includes word lines WL₂₁ to WL₂ₙ and N+ diffusion regions ND₂₁ to ND₂ₙ, and the word lines WL₂₁ to WL₂ₙ and N+ diffusion regions ND₂₁ to ND₂ₙ are intersect at right angles with each other. Memory cells of the memory cell block MB2 are formed at overlapping parts (shown by slanted lines) of the word lines WL₂₁ to WL₂ₙ and N+ diffusion regions ND₂₁ to ND₂ₙ and a part that is in contact with the drain is a bit line and a part that is not in contact with the drain is a source.

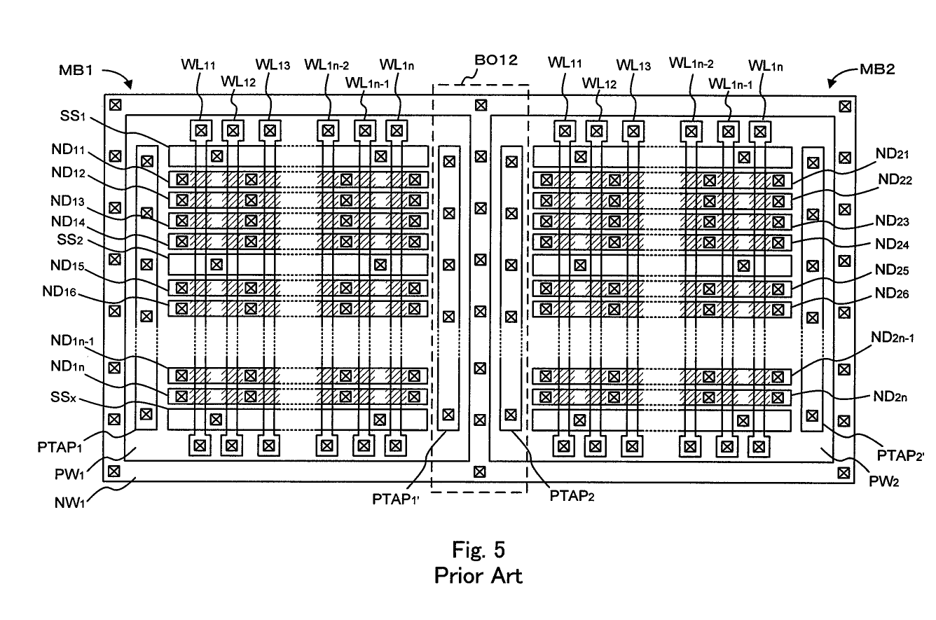

In FIG. 3, nodes PTAP₁ and PTAP₂ for applying a voltage to the P-type well region PW are electrically the same node, and the source straps SS₁ to SSₓ are shared by the two memory cell blocks. In addition, as can be seen from the layout chart in FIG. 3, since the memory cell array 10 of the device 1 of the present invention does not need a boundary region BO12 shown in FIG. 5, so that a chip area can be reduced.

When the erasing object block is designated by an external signal and the erasing process is to be performed, the high-voltage control circuit 20 converts the voltage from the charge pump 22 or the power supply pad 21 to generate the erasing positive voltage for the erasing process and supplies it to the high-voltage switches Sh1 and Sh2 and the source/well switch 50. At the time of erasing process, when the high-voltage switch Sh1 receives the erasing positive voltage from the high-voltage control circuit 20, it outputs the reference voltage to the row decoder 41 when the memory cell block MB1 is the erasing object block or outputs the erasing positive voltage to the row decoder 41 when the memory cell block MB1 is the non-erasing object block. Since the memory cell block MB1 is the erasing object block in the present embodiment, the high-voltage switch Sh1 outputs the reference voltage to the row decoder 41. Similarly, at the time of erasing process, when the high-voltage switch Sh2 receives the erasing positive voltage from the high-voltage control circuit 20, it outputs the reference voltage to the row decoder 42 when the memory cell block MB2 is the erasing object block or outputs the erasing positive voltage to the row decoder 42 when the memory cell block MB2 is the non-erasing object block. Since the memory cell block MB2 is the non-erasing object block in the present embodiment, the high-voltage switch Sh2 outputs the erasing positive voltage to the row decoder 42. The row decoder 42 applies the erasing positive voltage supplied from the high-voltage switch Sh2 to the word lines WL₂₁ to WL₂ₙ of the memory cell block MB2 at the time of the erasing process.

When the erasing object block is designated by an external signal and the erasing process is to be performed, the negative voltage control circuit 30 converts the voltage from a charge pump (not shown) to generate the erasing negative voltage for the erasing process and supplies it to the negative voltage switches Sn1 and Sn2. At the time of erasing process, the negative voltage switch Sn1 receives the erasing negative voltage from the negative voltage control circuit 30 and outputs the erasing negative voltage to the row decoder 41 when the memory cell block MB1 is the erasing object block or outputs the reference voltage to the row decoder 41 when the memory cell block MB1 is the non-erasing object block. Since the memory cell block MB1 is the erasing object block in the present embodiment, the negative voltage switch Sn1 outputs the erasing negative voltage to the row decoder 41. Similarly, at the time of erasing process, the negative voltage switch Sn2 receives the erasing negative voltage from the negative voltage control circuit 30 and outputs the erasing negative voltage to the row decoder 42 when the memory cell block MB2 is the erasing object block or outputs the reference voltage to the row decoder 42 when the memory cell block MB2 is the non-erasing object block. Since the memory cell block MB2 is the non-erasing object block in the present embodiment, the negative voltage switch Sn2 outputs the reference voltage to the row decoder 42.

At the time of the erasing process, the row decoder 41 applies the erasing negative voltage to the word lines WL₁₁ to WL₁ₙ of the memory cell block MB1 when the memory cell block MB1 is the erasing object block, or outputs the erasing positive voltage to them when the memory cell block MB1 is non-erasing object block. Since the memory cell block MB1 is the erasing object block in the present embodiment, the erasing negative voltage supplied from the negative voltage switch Sn1 is applied to the word lines WL₁₁ to WL₁ₙ of the memory cell block MB1.

At the time of the erasing process, the row decoder 42 applies the erasing negative voltage to the word lines WL₂₁ to WL₂ₙ of the memory cell block MB2 when the memory cell block MB2 is the erasing object block, or outputs the erasing positive voltage to them when the memory cell block MB2 is the non-erasing object block. Since the memory cell block MB2 is the non-erasing object block in the present embodiment, the erasing positive voltage supplied from the high-voltage switch Sh2 is applied to the word lines WL₂₁ to WL₂ₙ of the memory cell block MB2.

At the time of the erasing process, the source/well switch 50 receives the erasing positive voltage from the high-voltage control circuit 20 and applies the supplied erasing positive voltage to the P-type well region PW. Thus, since the voltages of the word lines WL₂₁ to WL₂ₙ of the memory cell block MB2 that is the non-erasing object block and the applied voltage to the P-type well region are the same erasing positive voltage, and there is no voltage difference between them, the programmed data in each memory cell constituting the memory cell block MB2 is not erased. Meanwhile, since the voltage of the word lines WL₁₁ to WL₁ₙ of the memory cells of the memory cell block MB1 that is the erasing object block is the erasing negative voltage and the voltage of the P-type well region PW is the erasing positive voltage, a voltage based on the voltage difference between the erasing positive voltage and the erasing negative voltage is applied to each memory cell constituting the memory cell block MB1, so that data is erased in the memory cells. According to the present embodiment, when it is assumed that the erasing positive voltage is 8 V and the erasing negative voltage is −8 V as shown in FIG. 2, a voltage of 16 V is applied to each memory cell constituting the memory cell block MB1 to perform the data erasing.

Furthermore, at the time of the erasing process, the device 1 of the present invention applies the high voltage to the P-type well region PW and at the same time applies the erasing positive voltage to the semiconductor substrate NW. Thus, the semiconductor substrate NW is insulated from the P-type well region.

### Second Embodiment

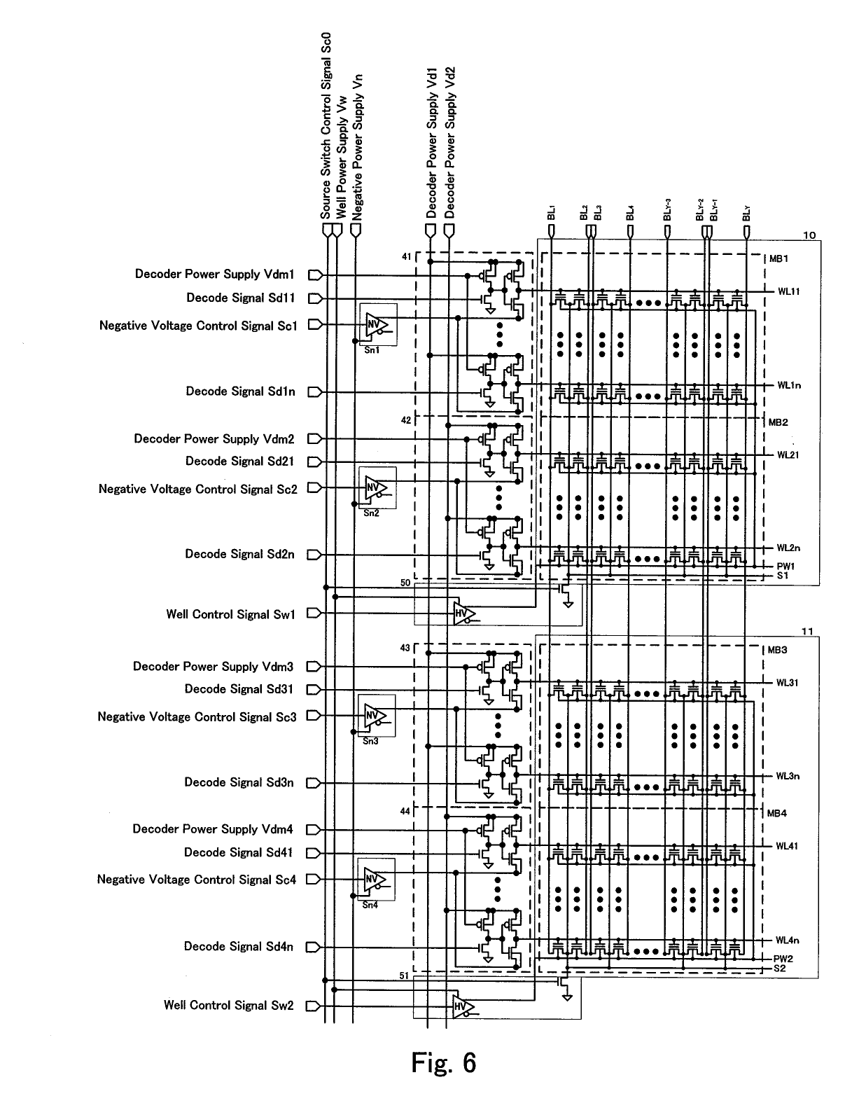

A second embodiment of the present invention will be described with reference to FIG. 6. In this embodiment, a case where the memory cell block has a different constitution from the first embodiment will be described in the present embodiment.

First, a constitution of the device of the present invention will be described with reference to FIG. 6. FIG. 6 is a schematic block diagram showing one example of a constitution regarding an erasing process of the device of the present invention. In addition, FIG. 6 illustrates a case where two memory cell block groups each including two memory cell blocks are formed for simplification.

The device of the present invention includes a memory cell array (memory cell block group) 1h (h=0, 1) in which memory cell blocks are formed in a common well region, a row decoder 4i that switches a voltage to be applied to word lines WLi1 to WLin of a memory cell block MBi (i=1 to 4) at the time of erasing process with respect to each memory block, a negative voltage switch Sni supplying an erasing negative voltage to the row decoder 4i based on a negative voltage control signal Sci, and a source/well switch 5h selectively applying an erasing positive voltage or a reference voltage with respect to each well region PWh based on a well control switch SWh. In addition, a well region PW1 of the memory cell array 10 is electrically separated from a well region PW2 of the memory cell array 11. In addition, the drains of the memory cells arranged in each column in the memory cell block MBi are connected to each of common bit lines BL₁ to BL_{Y} between the memory cell blocks. Furthermore, according to the present embodiment, since the number of the memory cell blocks included in each of the memory cell array 10 and the memory cell array 11 is two, two voltage supply sources shared by the memory cell array 10 and the memory cell array 11, that is, a decoder power supply Vd1 and a decoder power supply Vd2 are provided. In addition, the number of the voltage supply sources is equal to the number of the memory cell blocks included in each memory cell block group.

As shown in FIG. 6, the memory cell array 10 includes a memory cell block MB1 and a memory cell block MB2 in the common well region PW1. The memory cell block MB1 of the memory cell array 10 is connected to a row decoder 41 and the memory cell block MB2 is connected to a row decoder 42. Similarly, as shown in FIG. 6, the memory cell array 11 includes a memory cell block MB3 and a memory cell block MB4 in the common well region PW2. The memory cell block MB3 of the memory cell array 11 is connected to a row decoder 43 and the memory cell block MB4 is connected to a row decoder 44. In addition, the internal constitutions of the memory cell blocks MB1 to MB4 are the same as those in the first embodiment.

The row decoder 4i (i=1 to 4) is connected to either the decoder power supply Vd1 or the decoder power supply Vd2 that supplies the reference voltage or the erasing positive voltage. More specifically, according to the present embodiment, the row decoder 41 of the memory cell array 10 and the row decoder 43 of the corresponding memory cell array 11 are connected to the decoder power supply Vd1. Similarly, the row decoder 42 of the memory cell array 10 and the row decoder 44 of the corresponding memory cell array 11 are connected to the decoder power supply Vd2.

As shown in FIG. 6, the row decoder 4i (i=1 to 4) according to the present embodiment includes a voltage switching circuit for switching a voltage to be applied to the word lines WLi1 to WLin based on the decoder power supply Vdmi, decode signals Sdi1 to Sdin, and the negative voltage control signal Sci with respect to each of the word lines WLi1 to WLin of the memory cell block MBi. More specifically, the voltage switching circuit connected to the word line WLij (=1 to n) includes two stages of inverter circuits connecting the drain terminals of a PMOS transistor and an NMOS transistor, and the output of the second stage inverter circuit is connected to the word line WLij. In addition, the decoder power supply Vdmi is connected to the gate terminal of the PMOS transistor of the first stage inverter circuit, and the decode signal Sdij is connected to the gate terminal of the NMOS transistor. The connecting point (output) of the PMOS transistor and the NMOS transistor of the first stage inverter circuit is connected to the gate terminals of the PMOS transistor and the NMOS transistor of the second stage inverter circuit. The source terminal and the back gate terminal of the PMOS transistor of each inverter circuit are connected to the decoder power supply Vdk (when ‘T’ is an odd number, k=1, while “i” is an even number, k=2). The source terminal of the NMOS transistor of the first stage inverter circuit is grounded and the source terminal and the back gate terminal of the NMOS transistor of the second stage inverter circuit are connected to the negative voltage switch Sni.

According to the present embodiment, the negative voltage switch Sni (i=1 to 4) outputs the erasing negative voltage from a negative power supply Vn to the row decoder 4i when the negative voltage control signal Sci is set to “0” level.

The source/well switch 5h (h=0, 1) applies an erasing positive voltage from a well power supply Vw to the well region PWm (m=1, 2) when the well control signal SWh is set to “1” level. The source/well switch 5h comprises source switches connected to ground lines S1 and S2, respectively. The gates of the source switches are connected to a source switch control signal Sc0 in common.

Next, the erasing process of the device of the present invention according to the present embodiment will be described with reference to FIG. 6. Description will be made assuming that the memory cell block MB1 is an erasing object block, and the memory cell block group 10 is a selected memory cell block group.

According to the device of the present invention in the present embodiment, when the erasing process is performed to the memory cell block MB1 that is the erasing object block, the reference voltage is applied to the decoder power supply Vd1, the erasing positive voltage is applied to the decoder power supply Vd2, the erasing positive voltage is applied to the well power supply Vw, and the erasing negative voltage is applied to the negative power supply Vn. In addition, the erasing positive voltage is applied to decoder power supplies Vdm1 and Vdm2, and the reference voltage is applied to a decoder power supply Vdm4.

According to the present embodiment, in the memory cell array 10 (selected memory cell block group) containing the memory cell block MB1 (erasing object block), the device of the present invention performs the erasing process to the memory cell block MB1 by applying the erasing positive voltage to the well region PW1, the erasing negative voltage to all the word lines WL11 to WL1n contained in the memory cell block MB1, the erasing positive voltage to all the word lines WL21 to WL2n contained in the memory cell block MB2 (memory cell block except for the memory cell block MB1). Furthermore, the word lines WL31 to WL3n are brought to a floating state by applying a predetermined reference voltage to the well region PW2 and all word lines WL41 to WL4n contained in the memory cell block MB4, in the memory cell block group 11 (unselected memory cell block group) that does not contain the memory cell block MB1 of the erasing object block.

More specifically, in the memory cell array 10 that is the selected memory cell block group, the well control signal Sw1 for controlling the source/well switch 50 is set to “1” level and the erasing positive voltage is applied from the well power supply Vw to the well region PW1. In the memory cell block MB1 that is the erasing object block, when the negative voltage control signal Sc1 is set to “0” level, the negative voltage switch Sn1 supplies the erasing negative voltage from the negative power supply Vn to the row decoder 41. Furthermore, when the decode signals Sd11 to Sd1n are set to “1” level, since the erasing positive voltage is applied to the decoder power supply Vdm1, the row decoder 41 switches the output of the voltage switching circuit to be connected to the word lines WL11 to WL1n, to the erasing negative voltage from the negative voltage switch Sn1. Thus, the row decoder 41 applies the erasing negative voltage to the word lines WL11 to WL1n to perform the erasing process for the memory cell block MB1.

In the memory cell block MB2 formed in the well region PW1 shared with the memory cell block MB1, when the negative voltage control signal Sc2 is set to “1” level, the negative voltage switch Sn2 outputs the reference voltage (ground voltage) to the row decoder 42. Furthermore, when the decode signals Sd21 to Sd2n are set to “1” level, since the erasing positive voltage is applied to the decoder power supply Vdm2, the row decoder 42 switches the output of the voltage switching circuit connected to the word line WL21 to WL2n to the erasing positive voltage from the decoder power supply Vd2. Thus, the row decoder 42 applies the erasing positive voltage to the word line WL21 to WL2n, so that the erasing process is not performed in the memory cell block MB2.

In the memory cell array 11 that is the unselected memory cell block group, a well control signal SW2 for controlling the source/well switch 51 is set to “0” level and the reference voltage is applied to the well region PW2. In the memory cell block MB3, when a negative voltage control signal Sc3 is set to “1” level, a negative voltage switch Sn3 outputs the reference voltage (ground voltage) to the row decoder 43. Furthermore, when the decode signals Sd31 to Sd3n are set to “0” level, since the reference voltage is supplied from the decoder power supply Vd1 to the row decoder 43 regardless of the applied voltage of the decoder power supply Vdm3, the word lines WL31 to WL3n connected to the row decoder 43 are brought to a floating state. In this case, since the voltage difference generated between the gate terminals (word lines WL31 to 3n) of the memory cells included in the memory cell block MB3 and the well region PW2 can be considerably smaller than the voltage difference required for the erasing process (difference between the erasing positive voltage and the erasing negative voltage) because the word line voltage in the floating state does not exceed the threshold voltages of the PMOS transistor and the NMOS transistor from the reference voltage, so that the erasing process is not performed in the memory cell block MB3.

Similarly, regarding the memory cell block MB4 formed in the well region PW2 shared with the memory cell block MB3, when a negative voltage control signal Sc4 is set to “1” level, a negative voltage switch Sn4 outputs the reference voltage (ground voltage) to the row decoder 44. Furthermore, when decode signals Sd41 to Sd4n are set to “0” level, since the reference voltage is applied to a decoder power supply Vdm4, the row decoder 44 switches the output of the voltage switching circuit connected to the word lines WL41 to WL4n to the reference voltage from the negative voltage switch Sn4. In addition, the erasing positive voltage is supplied from the decoder power supply Vd2 to the row decoder 44. Thus, the row decoder 44 applies the reference voltage to the word lines WL41 to WL4n so that the erasing process is not performed in the memory cell block MB4.

As described above, when the erasing positive voltage is applied to the well region PW1 and the erasing negative voltage is applied to the word lines WL11 to WL1n in the memory cell array 10, the erasing process is executed to the memory cell block MB1, and when the erasing negative voltage is applied to the word lines WL21 to WL2n, the erasing process is not executed in the memory cell block MB2. In addition, when the word lines WL31 to WL3n in the memory cell block MB3 are brought to the floating state and the reference voltage is applied to the well region PW2 and the word lines WL41 to WL4n contained in the memory cell block MB4, the erasing process is not executed in the memory cell block MB3 and the memory cell block MB4. That is, the erasing process is executed for the memory cell block MB1 that is the erasing object block only.

Although description has been made of the case where the two memory cell block groups (memory cell arrays 1h (h=0, 1)) each including the two memory cell blocks are formed, the present invention is not limited thereto. Each memory cell block group may include two or more memory cell blocks and each memory cell block group may have different number of memory cell blocks. In addition, according to the present embodiment, when the plurality of memory cell blocks are formed in the common well region, as the number of the memory cells formed in the common well region is increased, a power supply having high driving ability is needed in order to apply the erasing positive voltage or the reference voltage to the well region at the time of erasing process. Thus, the number of the memory cell block groups and the number of memory cell blocks in each memory cell block group are to be determined in view of the proof stress and function of the device of the present invention and the driving ability of each power supply.

According to the device of the present invention in the present embodiment, since the common decoder power supplies Vd1 and Vd2 are used between the memory cell block groups, the chip area of the device of the present invention can be reduced as compared with the case where the decoder power supplies Vd1 and Vd2 are provided in each memory cell block group.

### Another Embodiments

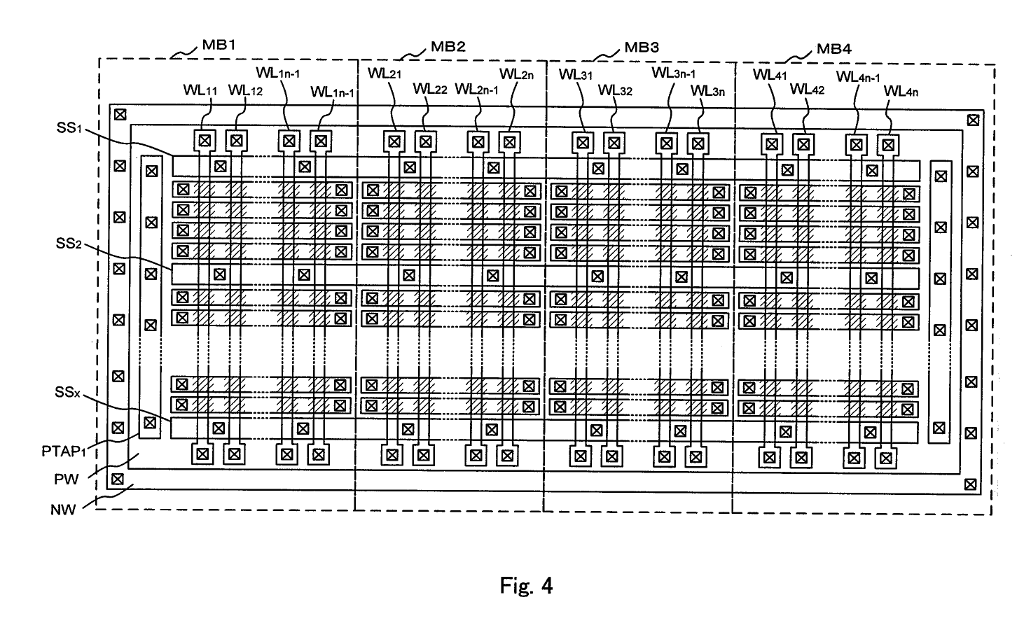

(1) Although description has been made of the case where the memory cell array is divided into the two memory cell blocks MB1 and MB2 in the above first embodiment, the memory cell array may be divided into three or more memory cell blocks and for example, may be divided into four memory cell blocks MB1 to MB4 as shown in FIG. 4. In this case also, similar to the first embodiment, when the erasing positive voltage is applied to the well region, the erasing negative voltage is applied to the word line of the erasing object block, and the erasing positive voltage is applied to the word line of the non-erasing object block, the erasing process can be performed with respect to each memory cell block.
(2) Although description has been made assuming that the semiconductor substrate is of N-type and the well region is of P-type in the above first and second embodiments, the present invention is not limited thereto, so that the semiconductor substrate may be of P-type and the well region may be of N-type.
(3) Although description has been made of the case where the two decoder power supplies Vd1 and Vd2 are commonly used in all the row decoders 41 to 44 in the constitution regarding the erasing process for simplification in the second embodiment, the present invention is not limited to thereto.

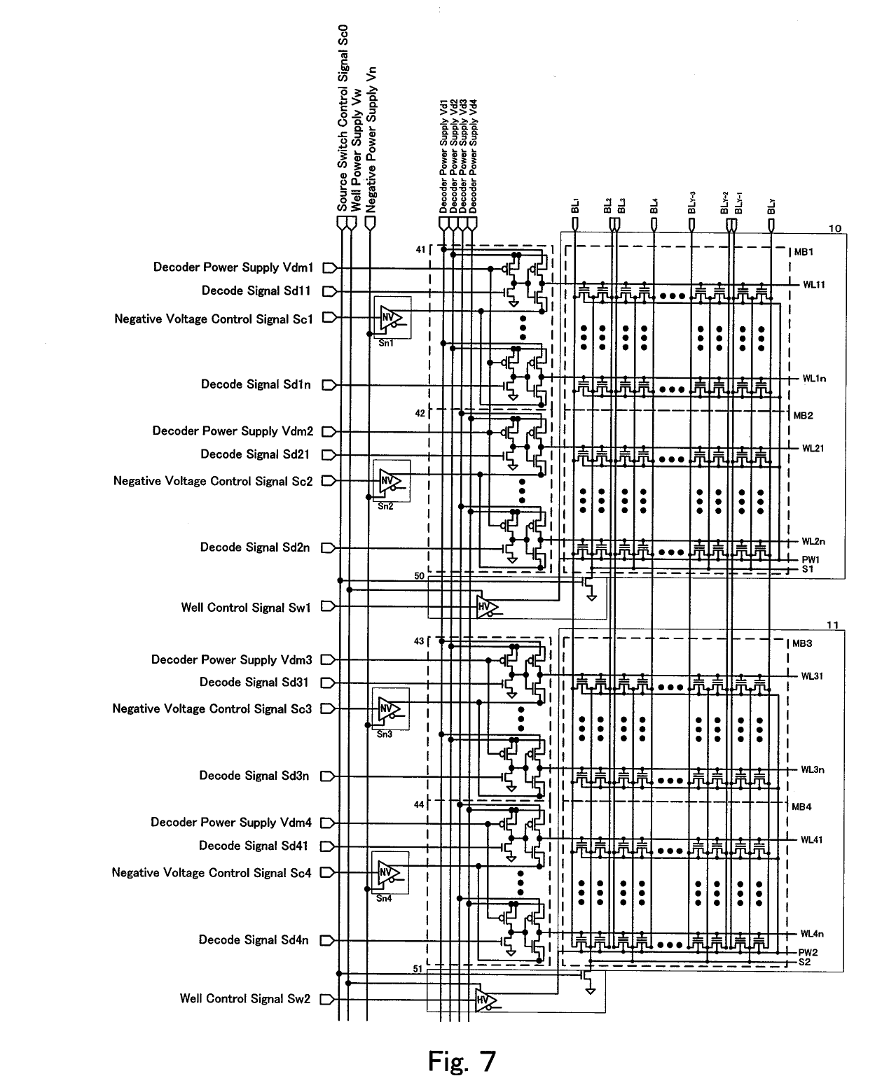

For example, in order to prevent the word line of the non-erasing object block from becoming the floating state, as shown in FIG. 7, according to the device of the present invention, four decoder power supplies Vd1 to Vd4 are provided, row decoders 4l (l=1, 3) are connected to the decoder power supplies Vd1 and Vd2, and a row decoders 4m (m=2, 4) are connected to the decoder power supplies Vd3 and Vd4. In this case, the row decoder 41 constitutes a voltage switching circuit such that the source terminal of a PMOS transistor constituting a second stage inverter circuit is connected to the decoder power supply Vd1, and the source terminal and the back gate terminal of a PMOS transistor constituting a first stage inverter circuit and the back gate terminal of the PMOS transistor constituting the second stage inverter circuit are connected to the decoder power supply Vd2. The row decoder 4m constitutes a voltage switching circuit such that the source terminal of a PMOS transistor constituting a second stage inverter circuit is connected to the decoder power supply Vd3, and the source terminal and the back gate terminal of a PMOS transistor constituting a first stage inverter circuit and the back gate terminal of the PMOS transistor constituting the second stage inverter circuit are connected to the decoder power supply Vd4.

Although the present invention has been described in terms of the preferred embodiment, it will be appreciated that various modifications and alternations might be made by those skilled in the art without departing from the spirit and scope of the invention. The invention should therefore be measured in terms of the claims which follow.

1. A nonvolatile semiconductor memory device comprising:
a memory cell array including a plurality of memory cells having an electrically writable MOS transistor structure provided by laminating a charge accumulation layer capable of accumulating electric charges and a control gate, the memory cell array being formed in a well region of a second conductivity type different from a first conductivity type, the well region being formed on a semiconductor substrate of the first conductivity type, wherein
the memory cell array includes the memory cells arranged in row and column directions like a matrix such that control gates of the memory cells in the same row are connected to a common word line, drains of the memory cells in the same column are connected to a common bit line, and sources of the memory cells at least in the same column or the same row are connected to a common ground line, and the memory cell array is divided into a plurality of memory cell blocks each including a plurality of word lines, and
an erasing process is performed with respect to each memory cell block by applying an erasing positive voltage to the well region, an erasing negative voltage to all the word lines contained in an erasing object block in the memory cell blocks, and the erasing positive voltage to the control gates of all the memory cells included in the memory cell blocks except for the erasing object block.

2. The nonvolatile semiconductor memory device according to claim 1 comprising:
a plurality of memory cell block groups each having the plurality of memory cell blocks formed in the common well region, the well region of the memory cell block group being electrically separated from the well region of an adjacent memory cell block group, wherein
the erasing process is further performed by applying a predetermined reference voltage to the well region, and either applying the reference voltage to all the word lines contained in all the memory cell blocks in an unselected memory cell block group that does not include the erasing object block or bringing to a floating state all the word lines contained in all the memory cell blocks in an unselected memory cell block group that does not include the erasing object block.

3. The nonvolatile semiconductor memory device according to claim 2, comprising:
a row decoder capable of switching a voltage to be applied to the word lines of each of the memory cell blocks at the erasing process with respect to each memory cell block, and
a voltage supply source provided for each memory cell block of the memory cell block group and switching to supply the reference voltage or the erasing positive voltage to the row decoder of one of the memory cell blocks in the memory cell block group, wherein
each of the voltage supply sources outputs the reference voltage when the erasing object block is included in the memory cell blocks receiving a voltage in common between the memory cell block groups, and outputs the erasing positive voltage when the erasing object block is not included therein.
